(19) United States
(12) Patent Application Publication
(10) Pub. No.: US 2011/0089438 A1
(43) Pub. Date: Apr. 21, 2011

(54) OPTO-ELECTRICAL ASSEMBLIES AND ASSOCIATED APPARATUS AND METHODS

(75) Inventors: Odd Robert Steijer, Bromma (SE); Hans Magnus Emil Andersson, Jarfalla (SE); Asa Christina Johansson, Kungsangen (SE); Lennart Per Olof Lundqvist, Jarfalla (SE); Sylvia Anna-Karin Ek, Upplands Vasby (SE); Maria Elisabeth Källén, Stockholm (SE)

(73) Assignee: ZARLINK SEMICONDUCTOR AB, Jarfalla (SE)

(21) Appl. No.: 12/581,371

(22) Filed: Oct. 19, 2009

(51) Int. Cl. H01L 33/00; H01L 21/50

(52) U.S. Cl. 257/82; 438/25; 257/E33.077; 257/E21.499

(57) ABSTRACT

Provided is a method of providing an opto-electrical assembly. The method comprises attaching a second electrical element to a carrier using a second attachment region at a second attaching temperature. The second attaching temperature is associated with the melting temperature of the second attachment region, such as the melting temperature of solder or the like. The carrier already comprises a first opto-electrical element having been attached to the carrier using a first attachment region at a first attaching temperature, whereby the first attaching temperature is associated with the melting temperature of the first attachment region. The method is provided such that the second attachment region has a lower melting temperature than the first attachment region such that the second attaching temperature is lower than the first attaching temperature. The resulting opto-electrical carrier assembly is compatible to industry-standard RoHS-compliant solder reflow attachment schemes to PCB and ceramic substrates (and similar).

### FIELD OF THE INVENTION

The present invention relates to the field of opto-electrical assemblies. In particular, the invention relates to methods of providing opto-electrical assemblies and their associated apparatus.

### BACKGROUND OF THE INVENTION

Optical devices typically comprise a plurality of opto-electrical elements or components provided together as opto-electrical assemblies. Such opto-electrical components include purely optical components, purely electrical components, and combined opto-electrical components, or the like. Examples of such components include diodes (e.g. laser diodes), microcontrollers (e.g. microcontrollers for use with diodes), power controllers/regulators, etc. Opto-electrical assemblies are comprised with optical device and allow for processing of optical signals.

Manufacturing of such optical devices, or opto-electrical assemblies for optical devices, can prove challenging. There is a need to provide a method of easily manufacturing such assemblies, but while maintaining tolerances and reducing the chance of unwanted stresses or defects, which may be detrimental to the operation of an assembly.

FIG. 1a is a plan view of an embodiment of an opto-electrical assembly as known in the art. FIG. 1b is a side view of the assembly of FIG. 1a. FIG. 1c is an enlarged view of an opto-electrical element used on the assembly of FIG. 1a. FIG. 1a shows a plan view of an opto-electrical assembly 100. Here, the assembly 100 is configured to communicate signals at high speed (e.g. 10 GHz and above). The assembly 100 comprises a transparent support 110, which is shown here as a glass or silicon carrier 110. Two first opto-electrical elements 120a, 120b are attached to the carrier 110. One of the first opto-electrical elements 120a is a 4-channel receiver, while the other first opto-electrical element 120b is a 4-channel transmitter. Two second opto-electrical elements 130a, 130b are also attached to the carrier 110. The second opto-electrical elements 130a, 130b are configured for use with the first opto-electrical elements 120a, 120b.

The first opto-electrical elements 120a, 120b are provided by optical die, such as a die comprising gallium arsenide, and/or indium phosphide, or the like. In this example, the co-efficient of thermal expansion of the carrier 110 is similar to, or the same as, the first opto-electrical elements 120a, 120b. That is to say that the co-efficient of thermal expansion is matched between the first opto-electrical elements 120a, 120b and the carrier 110. This helps reduce the risk of mechanical stresses between the first opto-electrical elements 120a, 120b and the carrier 110 over a large temperature range.

Here, second electrical elements 130a, 130b are provided by integrated circuits, such as drivers or amplifiers, or the like. The second electrical elements 130a, 130b may be provided such that they are dedicated elements (e.g. application specific integrated circuits, field programmable gate arrays, etc.), or may be programmed or programmable (e.g. programmable intelligent computers).

The carrier 110 comprises a communication pattern 140, which is a metalized pattern. In this example, the communication pattern 140 allows for communication between first opto-electrical elements 120a, 120b and respective second opto-electrical elements 130a, 130b. The communication pattern 140 allows also for communication from the first/second opto-electrical elements 120a, 120b, 130a, 130b to and from circuitry apparatus, such as printed circuit boards or substrate, etc, using connecting pads 150 provided at a perimeter region of the carrier 110.

In this example, the first opto-electrical elements 120a, 120b and the second opto-electrical elements 130a, 130b are flip chips.

FIG. 1b shows a side view of the assembly 100 of FIG. 1a, in which one of the first opto-electrical elements 120a and one of the second opto-electrical elements 130a are visible. FIG. 1c shows an enlarged view of a first opto-electrical element 120a. Here, an optical signal 160 is passing through the carrier 100 to reach one of the first opto-electrical elements 101a.

### SUMMARY OF THE INVENTION

Disclosed is a chip on glass design compatible with standard RoHS processes for PCB attachment.

According to a first aspect of the invention there is provided a method of providing an opto-electrical assembly, the method comprising attaching a second electrical element to a carrier using a second attachment region at a second attaching temperature, the second attaching temperature being associated with the melting temperature of the second attachment region, the carrier comprising a first opto-electrical element having been attached to the carrier using a first attachment region at a first attaching temperature, the first attaching temperature being associated with the melting temperature of the first attachment region; wherein the second attachment region has a lower melting temperature than the first attachment region such that the second attaching temperature is lower than the first attaching temperature.

The first and/or second attaching temperatures may be the melting temperature of the first and/or second attachment region. The first and/or second attachment region may comprise solder.

The method may comprise attaching a second electrical element to a communication path, such as a metalized pattern, of the carrier. The method may comprise attaching the second opto-electrical element to the carrier to allow for electrical communication between the first opto-electrical element and the second opto-electrical element.

One or both of the opto-electrical elements may be optical elements, such as optical die. The optical element(s) may be optical transmitter(s). The optical element(s) may be optical receiver(s). One or both of the first and second opto-electrical elements may be electrical elements, for example, electrical elements for use with optical elements. The electrical element(s) may be integrated circuits, which may be driver(s), amplifier(s), microcontroller(s), or the like. The electrical element(s) may be one or more of: programmable intelligent computer(s), field programmable gate array(s), application specific integrated circuit(s), or the like.

The second electrical element may be an integrated circuit and the first opto-electrical element may be an optical die. The second electrical element may be for use with the first opto-electrical element (e.g. to control the operation of the optical die).

The carrier may be at configured at least a portion thereof to allow the passage of an optical signal. The carrier may be partially of fully translucent. The carrier may be partially or fully transparent. The carrier may allow for an optical signal to pass through a portion in order to be communicated to/from the first and/or second opto-electrical elements. The carrier may be glass, such as Pyrex™. The carrier may be silicon.

The carrier and the first opto-electrical and/or second electrical element may have the same, or similar, co-efficient of thermal expansion. The first and/or second opto-electrical element may comprise gallium arsenide. The first and/or second opto-electrical element may comprise indium phosphide.

One or both of the first and second opto-electrical elements may by flip-chips.

The second attachment region may be comprised with the second opto-electrical element. The second attachment region may be comprised with the carrier. The second attachment region may comprise bumps. The second attachment region may have a melting temperature of roughly +220 degrees Celsius. The first attachment region may have a melting temperature of roughly +280 degrees Celsius.

The method may comprise providing an underfill with the second opto-electrical element. The underfill may be for reinforcing the second attachment region between the second opto-electrical element and the carrier. The underfill may be for reducing the chance of contaminants at the second attachment region.

The method may comprise attaching a plurality of second opto-electrical elements. The carrier may comprise a plurality of first opto-electrical elements.

The method may comprise attaching the first opto-electrical element to the carrier before attaching the second electrical element.

The first attachment region may be comprised with the first opto-electrical element. The first attachment region may be comprised with the carrier. The first attachment region may comprise bumps.

The method may comprise providing an underfill with the first opto-electrical element. The underfill may be for reinforcing the first attachment region between the first opto-electrical element and the carrier. The underfill may be for reducing the chance of contaminants at the attachment region.

The underfill of the first and/or second opto-electrical element may be transparent or translucent, for example silicon underfill. The underfill of the first and/or second opto-electrical element may comprise epoxy.

The method may comprise attaching a plurality of first opto-electrical elements.

The method may comprise attaching one or more further opto-electrical elements to the carrier using one or more further attachment regions at one or more further temperatures. The one or more further attachment regions may have lower melting temperatures than the first and/or second attachment region such that the one or more further temperatures are lower than the first and/or second attaching temperature.

The method may comprise attaching the carrier with circuit apparatus, such as a substrate. The circuit apparatus may be: printed circuit board; further carrier (e.g. transparent carrier), etc. The method may comprise attaching the carrier with the circuit apparatus such that the carrier can communicate with the circuit apparatus.

The method may comprise gluing the carrier with the circuit apparatus. The method may comprise using a conductive adhesive to attach the carrier to the circuit apparatus. The method may comprise using conductive connectors to attach the carrier to the circuit apparatus. The conductive connectors may be aluminium connectors (e.g. aluminium studs). The method may comprise using non-conductive adhesive with the connectors to attach the carrier to the circuit apparatus.

The method may comprise attaching the carrier to the circuit apparatus by using solder. The method may comprise attaching the carrier to the circuit apparatus at a temperature similar to that at which the second opto-electrical element is attached to the carrier. The method may comprise attaching the carrier to the circuit apparatus at a temperature that is lower than that at which the second opto-electrical is attached to the carrier.

The method may comprise providing an underfill at the attachment between the carrier and the circuit apparatus. The method may comprise attaching a heat dissipater to the first and/or second opto-electrical elements. The heat dissipater may be attached using an adhesive.

According to a second aspect of the invention there is a method comprising providing a opto-electrical assembly according to any features of the first aspect; comprising the opto-electrical assembly with further apparatus to provide an optical device.

The further apparatus may include any one or more of: lens; ferrules (such as fibre ferrules); fibre cables; electrical pads, such as electrical pads for external connection, etc.

According to a third aspect of the invention there is provided apparatus comprising a carrier; a first opto-electrical element attached to the carrier at a first attachment region; a second opto-electrical element attached to the carrier at a second attachment region such that the carrier allows for electrical communication between the first opto-electrical element and the second electrical element; and wherein the melting temperature of the second attachment region is lower than the melting temperature of the first attachment region.

The second electrical element may be an integrated circuit and the first opto-electrical element may be an optical die. The second electrical element may be for use with the first opto-electrical element to control the first opto-electrical element. The carrier may be configured such that the second electrical element is able to communicate signals, such as control signal, with the first opto-electrical element when attached to the carrier. One or both of the first and second electrical elements may be flip-chips.

According to a fourth aspect of the invention there is provided an optical device, the optical device comprising apparatus according to the third aspect.

The optical device may further comprise any one or more of: lens; ferrules (such as fibre ferrules); fibre cables; electrical pads, such as electrical pads for external connection, etc.

According to a fifth aspect of the invention there is provided a method comprising connecting an optical die to a metalized pattern of a glass support using a first solder connection at a first temperature, the first temperature being associated with the melting temperature of the first solder connection; then connecting an integrated circuit to the metalized pattern of the glass support using a second solder connection at a second temperature, the second temperature associated with the melting temperature of the first solder connection; wherein the first solder connection has a higher melting temperature than the second solder connection such that the first temperature is higher than the second temperature.

The co-efficient of thermal expansion of the optical die and the carrier may be matched. The optical die may be a flip chip. The integrated circuit may be a flip chip. The solder connection(s) may be bumps. The method may comprise providing underfill for at least one of the optical die and the integrated circuit.

The method may comprise further connecting the transparent support to a printed (or printable) circuit board.

According to a sixth aspect of the invention there is provided apparatus comprising a carrier having an attached first opto-electrical element, the co-efficient of thermal expansion of the first opto-electrical element and the carrier being matched; the carrier further having an attached second electrical element, the second electrical element attached using an attachment region, the apparatus further comprising an underfill at the attachment region, the underfill configured to support the attachment region.

The underfill may comprise an epoxy.

According to a seventh aspect of the invention there is an opto-electrical circuit assembly obtained from first aspect or fifth aspect.

According to a eighth aspect of the invention there is provided a method for providing an opto-electrical assembly, the method comprising attaching an optical element with a carrier so as to provide electrical communication between the carrier and the optical element, attaching subsequently an electrical element with the carrier so as to provide electrical communication between the carrier and the electrical element, the electrical element for use with the optical element; wherein the temperature at which the optical element is attached to the carrier is higher than the temperature at which the electrical element is attached to the carrier.

According to a ninth aspect of the invention there is provided apparatus comprising a carrier having attached first opto-electrical and second electrical elements, the first opto-electrical element in communication with the second electrical element using the carrier, the apparatus further comprising an heat dissipater, the heat dissipater in communication with one or both of the first and second opto-electrical elements.

The heat dissipater may be in communication with one or both of the first opto-electrical and second electrical elements using an adhesive. The adhesive may be in communication with the carrier.

Other aspects and advantages of embodiments of the invention will be readily apparent to those ordinarily skilled in the art upon a review of the following description.

### BRIEF DESCRIPTION OF THE DRAWINGS

Embodiments of the invention will now be described in conjunction with the accompanying drawings, wherein:

FIG. 1a is a plan view of an embodiment of an opto-electrical assembly as known in the art;

FIG. 1b is a side view of the assembly of FIG. 1a;

FIG. 1c is an enlarged view of an opto-electrical element used on the assembly of FIG. 1a;

FIGS. 2a, 2b and 2c show a method of attaching one opto-electrical element to a carrier in accordance with the teachings of this invention;

FIGS. 3a and 3b show a method of attaching a further opto-electrical element to the carrier of FIG. 2 in accordance with the teachings of this invention;

FIG. 4 shows an embodiment of an opto-electrical assembly comprising a heat dissipater in accordance with the teachings of this invention;

FIGS. 5a and 5b show an embodiment of an assembly comprised with a substrate;

FIG. 6 shows an embodiment of an optical module or device comprising an opto-electrical assembly; and

FIG. 7 shows an exemplary embodiment of a flowchart, showing underfilling.

This invention will now be described in detail with respect to certain specific representative embodiments thereof, the materials, apparatus and process steps being understood as examples that are intended to be illustrative only. In particular, the invention is not intended to be limited to the methods, materials, conditions, process parameters, apparatus and the like specifically recited herein.

### DETAILED DESCRIPTION OF THE DISCLOSED EMBODIMENTS

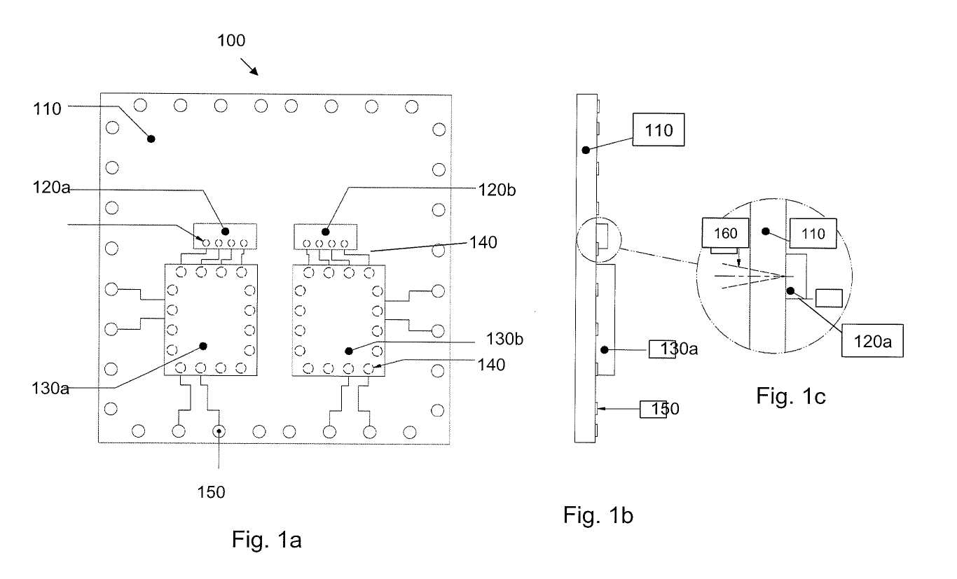

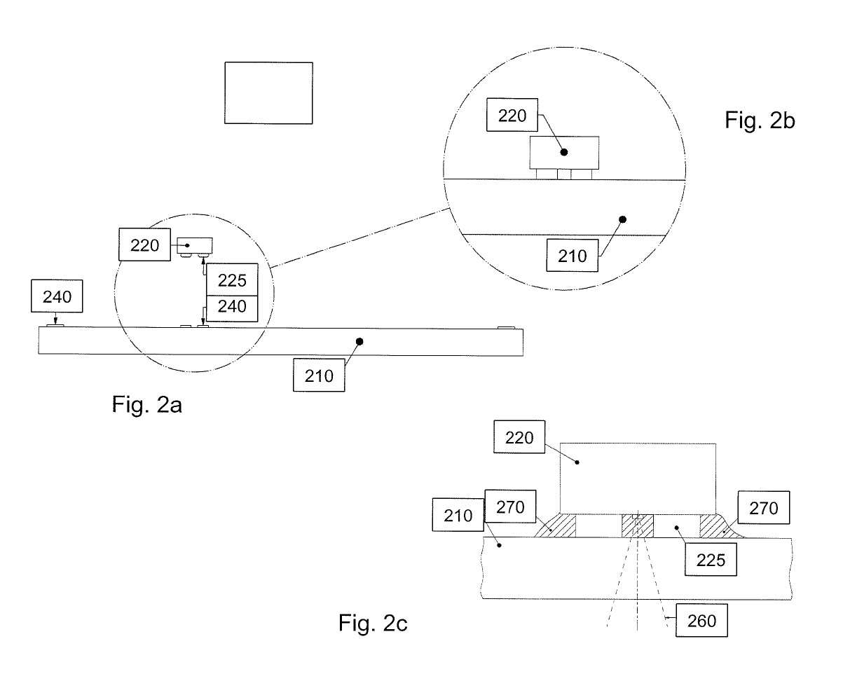

FIG. 2a shows a view of a carrier 210, having a communication pattern 240, in a similar manner to that described in relation to FIG. 1. FIG. 2a further shows a first opto-electrical element 220.

The first opto-electrical element 220 comprises a first attachment region 225. The first attachment region 225 is provided by solder bumps. The solder bumps here comprise gold and tin, and provide a eutectic mixture. The melting temperature of the first attachment region 225 is roughly 280 degrees Celsius. In the case the first attachment region 225 is caused to liquefy and then solidify in a known manner in order to allow for electrical and mechanical attachment of the first opto-electrical element 220 with the complementary portions of the pattern 240 of the carrier 210. Again, in this example, the first opto-electrical element 220 is an optical die, and is configured to communicate optical signals through the carrier 210.

FIG. 2b shows the first opto-electrical element 220 attached to the carrier 210. Of course, the first attachment region 225 may be provided with the carrier 210, rather than the first opto-electrical element 220, as will be appreciated.

Subsequent to attachment of the first opto-electrical element 220 to the carrier 210, an underfill 270a, 270b is provided in this example. The underfill 270a, 270b allows for volume, such as interstitial volume, between the first opto-electrical element 220 and the carrier 210 to be filled. FIG. 2c shows the underfill 270a, 270b provided at the first attachment region 225. Here, the underfill 270a, 270b comprises an epoxy, or similar. The underfill 270a, 270b reduces the chance of contaminates being introduced between the first opto-electrical element 220 and the carrier 210. The underfill 270a, 270b serves also to support the first attachment region 225. Here, the underfill 270a, 270b is transparent, and thus allow optical signals 260 to be communicated through carrier 210 to and from the first opto-electrical element 220.

A similar process can be provided to attach other first opto-electrical elements. It will be appreciated more than one first opto-electrical elements 220 may be attached at the same time, or at a similar time.

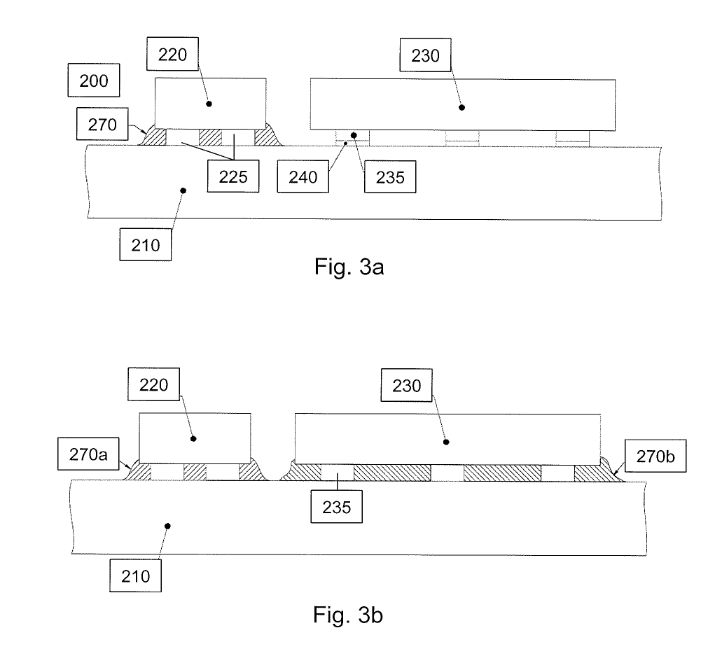

FIG. 3a shows the subsequent attachment a second electrical element 230 to the carrier 100 to provide an assembly 200. In a similar manner to that described in relation to FIG. 1, the second electrical element 230 is an integrated circuit, such as a driver or amplifier, or the like, for use with the first opto-electrical element 220.

The opto-electrical element 230 comprises a second attachment region 235 having solder bumps for attachment with the complementary pattern 240 of the carrier 210. In some embodiments, the second attachment region 235 is provided initially with the carrier 210, as will be appreciated.

Here, the solder bumps again comprise silver and tin and provide a eutectic mixture. The second attachment region 235 has a melting temperature of roughly 220 degrees Celsius. That is to say that the temperature at which the second attachment region 235 need to be heated in order for the solder bumps to liquefy is less that the melting temperature of the first attachment region 225. As such, when the second electrical element 230 is attached to the carrier 210, the first attachment region 225, having been fixed to the carrier 210 already, is not significantly affected.

A similar process can be provided to attach other second-electrical elements. It will be appreciated that more than one second electrical elements 230 may be attached at the same time, or at a similar time.

Because the positioning of the second electrical element 230 (in this case an integrated circuit) does not significantly affect the first attachment region 225 of the first opto-electrical element 220, the accuracy of the position of the first opto-electrical element 220 is maintained. Similarly, both the first and second opto-electrical elements can be located in relatively close proximity with each other. This reducing the risk of parasitic effects, and thus the speed of communication of signals in the assembly can be increased, compared to assemblies having distant components.

FIG. 3b shows the application of an underfill 270a, 270b with the second electrical element 230. The underfill 270a, 270b is an epoxy, or the like. However, in addition to providing protection against contamination, the underfill 270a, 270b is further selected to provide structural support for the second attachment region 235. Because the coefficient of thermal expansion of the carrier 210 is provided such that it matched with that of the first opto-electrical element 220, then it need not always be matched with the co-efficient of thermal expansion of the second opto-electrical element 230, which may result in unwanted stresses during use. It should be noted that underfill 270a for the opto-electric element 220 is transparent, while underfill 270b for the electrical element 230 is not necessarily transparent.

Therefore, the second electrical element underfill 270a, 270b can strengthen the join between the carrier 210 and the second electrical element 230 against such stress (e.g. thermal stresses), and thus improve reliability during manufacture and in lifetime of the assembly 200. Of course, in some examples, neither the first opto-electric element nor the second electrical element 220 & 230 may be provided with an underfill 270a, 270b. Alternatively, only the second electrical element 230 may be provided with an underfill.

Opto-electrical and electrical elements 220, 230, and in particular optical die and the like, require significant precision when being located in order to allow for accurate alignment of that element with further optical signal producing or receiving apparatus. Providing the above method allows for the alignment or position of the first opto-electrical element to be maintained, even when there is a need or desire to attach second electrical elements. Similarly, attaching the second electrical element 230 in the above described manner provides robust continuity of the electrical connection between the first opto-electrical element 220 and the carrier 210. In addition, a skilled reader will appreciate that because the same technique of application (e.g. soldering) is used, then the same manufacturing apparatus can be used to apply the first opto-electrical and second electrical elements 220, 230. The described methodology also mitigates the risk of hazardous substances used during manufacture, such as leaded solder, etc.

It will be appreciated that in some instances one first opto-electrical element 220 and a plurality of second electrical elements 230 may be provided. Likewise, the carrier 210 may comprise a plurality of first opto-electrical elements 220 and only one second electrical element 230. Then again, the carrier 210 may comprise a plurality of first opto-electrical elements 220 and a plurality of second electrical elements 230.

However, in each case the assembly process follows a temperature hierarchy. That is to say that the temperature at which first opto-electrical elements 220 are attached to the carrier 210 is higher than the temperature at which second electrical elements 230 are attached to the carrier 210.

Of course, the method may comprise providing further electrical elements, after the second electrical elements 230. In that case, it may be desirable to provide further attachment regions for the further electrical elements that have a lower melting temperature. Therefore, the further electrical elements could be attached at a further temperature, where the further temperature is lower than the temperature at which the first opto-electrical and second electrical elements 220, 230 were attached.

It will be appreciated that underfills 270a, 270b should be provided to any one or more of the opto-electrical or electrical elements 220, 230, then underfill 270a, 270b material may be selected, or temperatures for attachment selected, such that the subsequently applied heat does not adversely affect the properties of the underfill 270a, 270b (e.g. does not cause opacity in underfills 270a, 270b provided with an optical die, or the like).

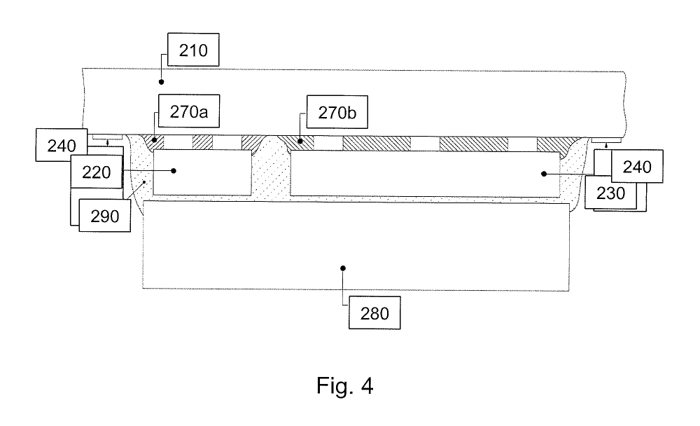

FIG. 4 shows the assembly 200 of FIG. 3, comprising carrier 210 and first opto-electrical and second electrical elements 220, 230 attached to the carrier 210. The assembly 200 is inverted from that shown in FIG. 3.

Here, the assembly 200 further comprises a heat dissipater 280. The heat dissipater 280 is attached to the first opto-electrical and second electrical elements 220, 230 using an adhesive 290. In this embodiment, the adhesive 290 is also in communication with the carrier 210 such that the adhesive 290 acts as a sealant to fully or partially surround the first opto-electrical and second electrical elements 220, 230. Here, the heat dissipater is configured to attach to a heat sink, such as casing of an optical device or module. Of course, in some examples of providing the assembly 200 of FIG. 4, the first opto-electrical and second electrical elements 220, 230 are attached to the carrier 210 at the same time, and/or at the same temperature.

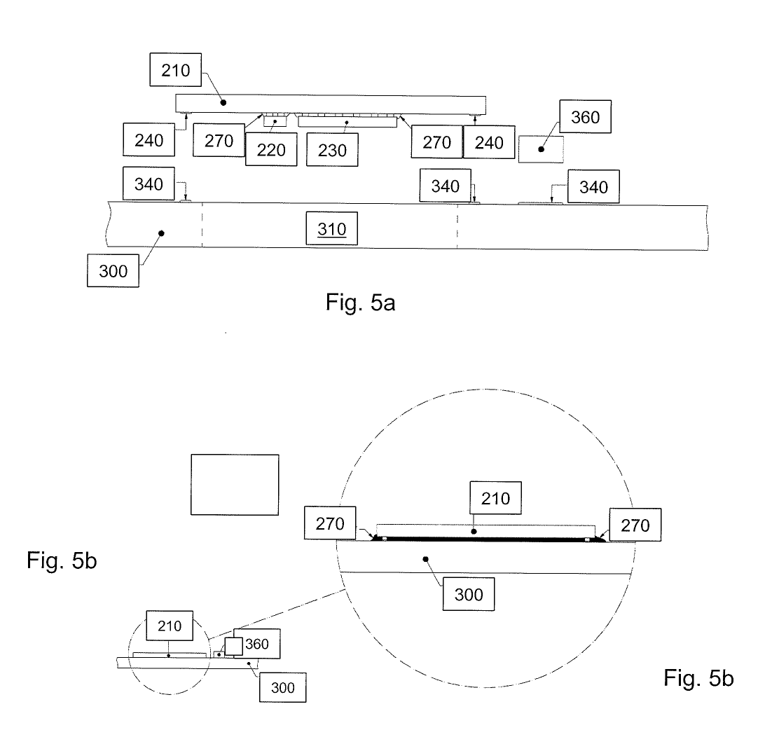

FIG. 5a shows the assembly 200 without the heat dissipater 280 and for attachment with circuit apparatus 300, which in this example is a substrate 300, such as a printed circuit board, or the like. It will be appreciated that such a substrate 300 may allow for the attachment or integration of the carrier 210 with further apparatus, such as optical devices or module, etc. Of course, it will be appreciated that in some examples the assembly 200 shown in FIG. 5 may comprise a heat dissipater 280, as described with reference to FIG. 4.

In this example, the substrate 300 comprises an aperture 310. The substrate 300 further comprises a complementary communication pattern 340, configured, when positioned, to communicate with the pattern 240 of the carrier 210. The communication pattern 340 of the substrate 300 may be provided by screen printed, or deposition, such as solder deposition. The communication pattern 340 allows for signals to be communicated using the substrate 300 to/from the carrier 210.

The aperture 310 is arranged to accept the protrusion of the first opto-electrical and second electrical elements 220, 230 on the carrier 210 (e.g. in a complementary manner). By way of an example, FIG. 5a further shows a surface mounted technology element 360 (e.g. capacitor, integrated circuit, amplifier, etc.) for attaching to the substrate 300. The surface mounted technology element 360 is for use when communicating signals to and from the carrier 210.

During manufacture, the carrier 210 is attached to the substrate 300 in a similar manner to that described above. For example, the carrier 210 and/or the substrate are provided with attachment regions, such as solder attachment regions. Those attachment regions have a melting temperature less than that of the first attachment region 225, and less than that of the second attachment region 235. The attachment region of the substrate/carrier is provided having melting temperature in the region of +200 degrees Celsius. A solder based on silver and tin, comprising indium and/or bismuth may be used. Similarly, a lead-tin solder may be used.

Of course, in some instances, the melting temperature of the attachment region between the carrier 210 and the substrate 300 may be the same or similar to that of the second attachment region 235 (e.g. when the second opto-electrical element 230 is an integrated circuit). However, in such instances, the underfill 270a, 270b of the first opto-electric element and the second electrical element 230 may allow for any re-flow.

FIG. 5b shows the assembly 200 in which the carrier 210 has been attached to the substrate 300. FIG. 5c shows an enlarged view of the attachment region between the carrier 210 and the substrate 300, which has been underfilled with an underfill 370. Again, epoxy, or the like can be used.

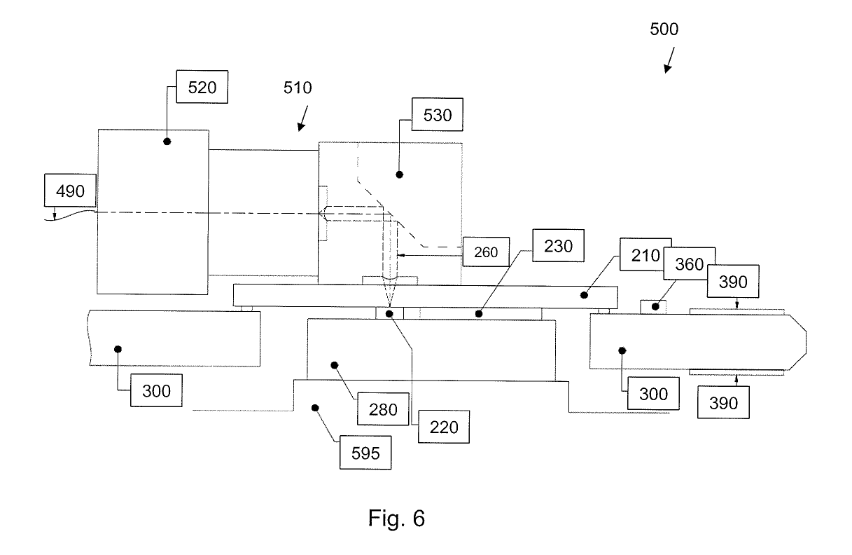

FIG. 6 shows a portion of an optical device 500 or module, comprising an assembly 100, 200 as described above. The device 500 comprises an optical fiber guide 510 having a ferrule portion 520 and a lens portion 530, in order to allow for communicating an optical signal to/from the first opto-electrical element 220. The lens 530 is configured to communicate an optical signal with the first opto-electrical element 220 through the carrier 210. In this example, both the first opto-electrical and second electrical elements are in thermal communication with the heat dissipater 280 (as described in with reference to FIG. 4), and in addition with casing 595 of the device 500 to allow for heat to be readily dissipated from the first opto-electrical and second electrical elements 220, 230. The carrier 210 is in communication with the substrate 300, which is shown here with module connectors 390 to allow signals to be provided to and from the carrier 210 from further apparatus.

It will readily be appreciated that the device 500 as described in relation to FIG. 6 may also have more than one first opto-electrical and second electrical elements 220, 230, such as that described in relation to FIG. 1. Specifically, the device 500 may have one first opto-electrical element 220 acting as a transmitter, and one first opto-electrical element 220 acting as a receiver.

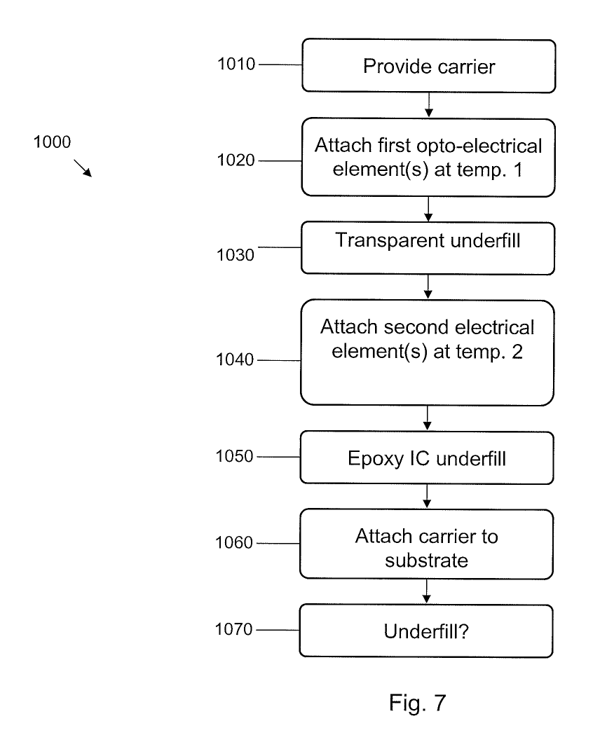

FIG. 7 shows a flowchart 1000 of the steps taken when providing an opto-electrical assembly 100, 200. Firstly a carrier 210 is provided 1010, such as a glass carrier 210. A first opto-electrical element 220 (e.g. an optical die, or the like) is attached 1020 to the carrier at a first temperature (temp. 1). Underfill 270a, 270b is then provided 1030 at a first attachment region 225 between the carrier 210 and the first opto-electrical element 220. A second electrical element is then attached 1040 to the carrier at a second temperature (temp. 2), whereby the second temperature is less than the first temperature. Again, underfill 270a, 270b is provided 1050. Of course, underfill 270a, 270b may be provided to both the first and second attachment region after the application of the second electrical element, or not at all in some instances. The carrier 200 is then attached 1060 to the substrate 300 to allow for communication with further apparatus. Underfill is provided 1070 at the attachment region between the carrier and the substrate 300.

While in the above examples, attachment regions 225, 235 have been described as being solder, it will be appreciated that any other suitable attachment region may be used, such as an adhesives with particular melting, or bonding, temperatures.

Similarly, in some examples the carrier 210 may be glued to the substrate. In such cases, the glue can comprise a conductive adhesive to attach the carrier 210 to the substrate 300. In a similar manner, when conductive connectors with studs are used, the adhesive can comprise a non-conductive adhesive.

It will be appreciated that any of the aforementioned first/second opto-electrical elements, carriers, circuit apparatus, devices, etc., may have other functions in addition to the mentioned functions, and that these functions may be performed by the same circuit/apparatus/elements.

Numerous modifications may be made without departing from the spirit and scope of the invention as defined in the appended claims.

What is claimed is:

1. A method of providing an opto-electrical assembly, the method comprising:
attaching a second electrical element to a carrier using a second attachment region at a second attaching temperature, the second attaching temperature being associated with the melting temperature of the second attachment region, the carrier comprising a first opto-electrical element having been attached to the carrier using a first attachment region at a first attaching temperature, the first attaching temperature being associated with the melting temperature of the first attachment region;
wherein the second attachment region has a lower melting temperature than the first attachment region such that the second attaching temperature is lower than the first attaching temperature.

2. The method according to claim 1 wherein the first and second attachment region comprise solder, and the first and second attaching temperatures are the melting temperature of the first and second attachment region.

3. The method according to claim 1 in which the method comprises attaching the second electrical element to a metalized communication path of the carrier to allow for electrical communication between the first opto-electrical element and the second electrical element.

4. The method according to claim 1 in which the second electrical element is an integrated circuit and the first opto-electrical element is an optical die.

5. The method according to claim 1 in which the carrier is partially or fully transparent and allows for an optical signal to pass through a portion in order to be communicated with the first opto-electrical element.

6. The method according to claim 5 wherein the carrier comprises glass or silicon.

7. The method according to claim 1 wherein the carrier and the first opto-electrical element have a matched co-efficient of thermal expansion.

8. The method according to claim 1 wherein one or both of the first opto-electrical and second electrical elements are flip-chips.

9. The method according to claim 1 wherein further comprising providing an underfill with the second electrical element, the underfill for reinforcing the second attachment region between the second electrical element and the carrier.

10. The method according to claim 1 comprising attaching the first opto-electrical element to the carrier before attaching the second electrical element.

11. The method according to claim 10 comprising providing a transparent underfill with the first opto-electrical element, the underfill for reducing the risk of contaminants at the attachment region, wherein the underfill is chosen to withstand subsequent reflow steps.

12. The method according to claim 1 comprising attaching the carrier with circuit apparatus, such as a substrate, such that the carrier can communicate with the circuit apparatus.

13. The method according to claim 12 comprising attaching the carrier to the circuit apparatus at a temperature similar or lower to that at which the second-electrical element is attached to the carrier.

14. The method according to claim 13 comprising providing an underfill at the attachment between the carrier and the circuit apparatus.

15. A method comprising:
providing a opto-electrical assembly according to any features of the first aspect;
comprising the opto-electrical assembly with further apparatus to provide an optical device.

16. The method according to claim 15, wherein the further apparatus includes any one or more of: lens; ferrules, fibre cables; electrical pads, such as electrical pads for external connection, heat dissipater.

17. An apparatus comprising:
a carrier;
a first opto-electrical element attached to the carrier at a first attachment region
a second electrical element attached to the carrier at a second attachment region such that the carrier allows for electrical communication between the first opto-electrical element and the second electrical element; and
wherein the melting temperature of the second attachment region is lower than the melting temperature of the first attachment region.

18. The apparatus according to claim 17, wherein the second electrical element is an integrated circuit and the first opto-electrical element is an optical die.

19. A method comprising:
connecting an optical die to a metalized pattern of a glass support using a first solder connection at a first temperature, the first temperature being associated with the melting temperature of the first solder connection;
then connecting an integrated circuit to the metalized pattern of the glass support using a second solder connection at a second temperature, the second temperature associated with the melting temperature of the first solder connection;
wherein the first solder connection has a higher melting temperature than the second solder connection such that the first temperature is higher than the second temperature.

20. An apparatus comprising:
a carrier having an attached first opto-electrical element, the co-efficient of thermal expansion of the first opto-electrical element and the carrier being matched;
the carrier further having an attached second electrical element, the second electrical element attached using an attachment region, the apparatus further comprising an underfill at the attachment region, the underfill configured to support the attachment region.

21. The apparatus according to claim 21, wherein the underfill comprises an epoxy.
